(19) United States
(12) Patent Application Publication
(10) Pub. No.: US 2026/0324250 A1
(43) Pub. Date: Oct. 15, 2026

(54) DISPLAY APPARATUS

(71) Applicant: LG Display Co., Ltd., Seoul (KR)

(72) Inventors: Taekyun KIM, Paju-si (KR); Jonghyun YANG, Paju-si (KR); Choonghoon LEE, Paju-si (KR)

(73) Assignee: LG Display Co., Ltd., Seoul (KR)

(21) Appl. No.: 19/361,589

(22) Filed: Oct. 17, 2025

(30) Foreign Application Priority Data
Dec. 12, 2024 (KR) 10-2024-0184888

(51) Int. Cl. H10K 59/80; H10K 59/121

(52) U.S. Cl. CPC H10K 59/80517; H10K 59/1213

(57) ABSTRACT

A display apparatus according to one or more examples includes a substrate on which a first sub-pixel, a second sub-pixel, and a third sub-pixel are disposed, a first circuit line disposed on the substrate, a thin film transistor disposed between the substrate and the first circuit line, a first protective layer disposed on the first circuit line and the thin film transistor, a second circuit line disposed on the first protective layer, a second protective layer disposed on the second circuit line, and a first anode electrode of the first sub-pixel disposed on the second protective layer, wherein the first protective layer has a different thickness in an area in which the first protective layer overlaps the first anode electrode.

### CROSS-REFERENCE TO RELATED APPLICATIONS

The present application claims the benefit of and priority to Korean Patent Application No. 10-2024-0184888, filed Dec. 12, 2024, the entire contents of which are incorporated herein by reference for all purposes.

### BACKGROUND

### 1. Technical Field

The present specification relates to a display apparatus.

### 2. Description of Related Art

As the information society develops, various demands for display apparatuses for displaying images are increasing, and various types of display apparatuses, such as a liquid crystal display (LCD) apparatus and an organic light emitting diode (OLED) display apparatus, are being utilized.

Among the display apparatuses, there is an advantage in that the OLED display apparatus as the self-luminous type has a wider viewing angle and a higher contrast ratio, and can be lighter and thinner and has lower power consumption because it does not require a separate backlight than the LCD apparatus. In addition, there is an advantage in that the OLED display apparatus can drive at a low voltage, have a fast response time, and especially have the inexpensive manufacturing cost.

The description of related art should not be considered prior art merely because it is mentioned in or associated with this section. The description of related art includes information that describes one or more aspects of the subject technology, and the description in this section does not limit the scope of the invention.

### SUMMARY

One or more aspects of the present specification are directed to providing a display apparatus in which it is possible to improve flatness of an anode electrode.

One or more aspects of the present specification are also directed to providing a display apparatus in which it is possible to smoothly implement the shape of a convex anode electrode.

One or more aspects of the present specification are also directed to providing a display apparatus in which it is possible to improve the color viewing angle characteristics.

Aspects of the present specification are not limited to the above-described aspects, and other technical aspects may be inferred from the following embodiments.

According to one embodiment of the present specification, there is provided a display apparatus including a substrate on which a first sub-pixel, a second sub-pixel, and a third sub-pixel are disposed, a first circuit line disposed on the substrate, a thin film transistor disposed between the substrate and the first circuit line, a first protective layer disposed on the first circuit line and the thin film transistor, a second circuit line disposed on the first protective layer, a second protective layer disposed on the second circuit line, and a first anode electrode of the first sub-pixel, which is disposed on the second protective layer, wherein the first protective layer has a different thickness in an area in which the first protective layer overlaps the first anode electrode.

According to another embodiment of the present specification, there is provided a display apparatus including a substrate on which a first sub-pixel, a second sub-pixel, and a third sub-pixel are disposed, a first circuit line disposed on the substrate, a thin film transistor disposed between the substrate and the first circuit line, a first protective layer disposed on the first circuit line and the thin film transistor, a second circuit line disposed on the first protective layer, a second protective layer disposed on the second circuit line, and a first anode electrode of the first sub-pixel, which is disposed on the second protective layer, wherein, in an area in which the first protective layer overlaps the first anode electrode, the first protective layer includes a trench recessed in a thickness direction, and the second circuit line is disposed in the trench.

Detailed matters of other embodiments are included in the detailed description and accompanying drawings.

According to the embodiments of the present specification, it is possible to improve the flatness of the anode electrode.

According to the embodiments of the present specification, it is possible to smoothly implement the shape of the convex anode electrode.

According to the embodiments of the present specification, it is possible to improve the color viewing angle characteristics.

According to the embodiments of the present specification, it is possible to improve the color viewing angle characteristics, thereby enabling the low-power driving of the display apparatus and reducing power consumption.

However, effects obtainable from the present specification are not limited to the above-described effects, and other effects that are not mentioned will be able to be clearly understood by those skilled in the art to which the present specification pertains based on the following description.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a schematic view illustrating a configuration of a display apparatus according to embodiments of the present disclosure.

FIG. 2 is a circuit diagram of a sub-pixel according to an embodiment of the present disclosure.

FIG. 3 illustrates a flat surface structure of a display panel according to one embodiment.

FIG. 4 is a cross-sectional view taken along line A-A′ in FIG. 3.

FIG. 5 is a cross-sectional view taken along line B-B′ in FIG. 3.

FIG. 6 is a specific cross-sectional view of a light-emitting part of FIG. 4.

FIG. 7 is a specific cross-sectional view of a light-emitting part according to a modified example.

FIG. 8 is a cross-sectional view of a touch part according to FIG. 4.

FIG. 9 is a cross-sectional view of a sub-pixel according to another embodiment.

FIG. 10 is a cross-sectional view of a sub-pixel according to still another embodiment.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Hereinafter, embodiments will be described with reference to the accompanying drawings. In the specification, when a first component (or an area, a layer, a portion, etc.) is described as “on,” “connected,” or “coupled to” a second component, it means that the first component may be directly connected/coupled to the second component or a third component may be disposed therebetween.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

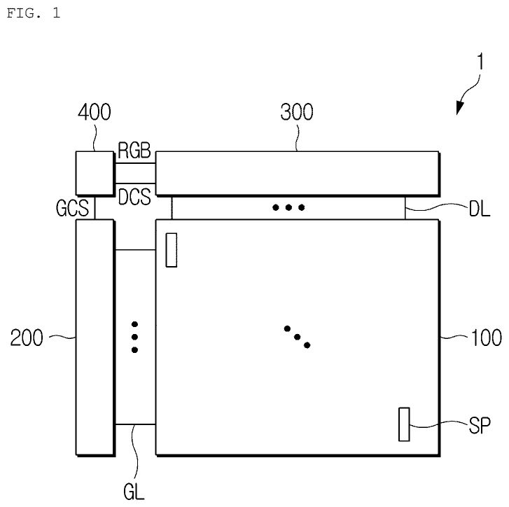

FIG. 1 is a schematic view illustrating a configuration of a display apparatus according to embodiments of the present disclosure.

Referring to FIG. 1, a display apparatus 1 according to embodiments of the present disclosure may include a display panel 100 for displaying a video, an image, etc., a gate driving circuit 200 and a data driving circuit 300 for driving the display panel 100, a controller 400, etc..

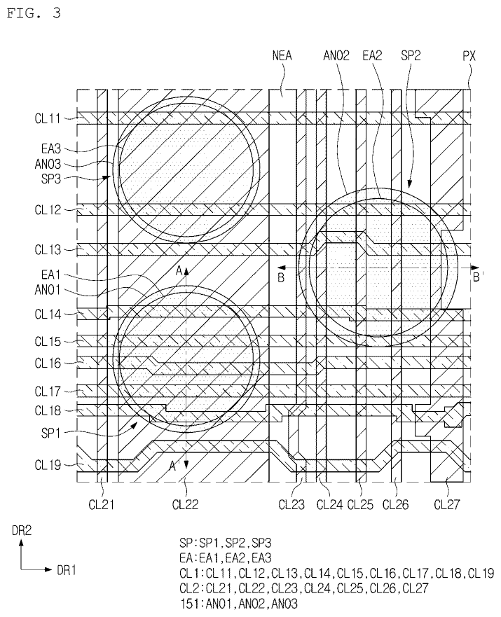

A plurality of sub-pixels SP may be disposed on the display panel 100. The sub-pixel SP may be repeatedly disposed in a first direction DR1 and a second direction DR2 (see FIG. 3).

In embodiments, the first direction DR1 and the second direction DR2 may refer to different directions and intersecting directions. For example, the first direction DR1 and the second direction DR2 refer to directions that intersect each other vertically in a plan view. In FIG. 1, the first direction DR1 may refer to a left-right direction in a plan view, and the second direction DR2 may refer to a vertical direction in a plan view. However, the directions described in the embodiments should be understood as indicating relative directions, and the embodiments are not limited to the described directions.

On the display panel 100, a plurality of gate lines GL and a plurality of data lines DL are disposed, and the sub-pixel SP is disposed in an area defined by the intersection of the gate line GL and the data lines DL.

The gate driving circuit 200 is controlled by the controller 400 and sequentially outputs scan signals to the plurality of gate lines GL disposed on the display panel 100 to control the driving timing of the plurality of sub-pixels SP.

In some cases, the gate driving circuit 200 may output a scan signal for controlling the driving timing of the sub-pixel SP and a light-emitting control signal for controlling the light-emitting timing of the sub-pixel SP. In this case, the circuit for outputting the scan signal and the circuit for outputting the light-emitting control signal may be implemented as separate circuits or implemented as a single circuit.

The gate driving circuit 200 may include one or more gate driver integrated circuits (GDIC) and may be located at only one side or both sides of the display panel 100 according to a driving method.

Each gate driver integrated circuit (GDIC) may be connected to a bonding pad of the display panel 100 by a tape automated bonding (TAB) method, a chip on glass (COG) method, or a chip on plastic (COP) method or implemented as a gate in panel (GIP) type and disposed directly on the display panel 100, and in some cases, may be integrally disposed on the display panel 100. In addition, each gate driver integrated circuit (GDIC) may be implemented by a chip on film (COF) method mounted on a film connected to the display panel 100.

The data driving circuit 300 receives image data RGB from the controller 400 and converts the image data RGB into an analog data voltage. In addition, the data driving circuit 300 outputs the data voltage to each data line DL according to the timing at which the scan signal is applied through the gate line GL so that each sub-pixel SP exhibits brightness according to the image data.

The data driving circuit 300 may include one or more source driver integrated circuits (SDIC).

Each source driver integrated circuit (SDIC) may include a shift register, a latch circuit, a digital to analog converter (DAC), an output buffer, etc.

Each source driver integrated circuit (SDIC) may be connected to a bonding pad of the display panel 100 by a TAB method, a COG method, or a COP method or disposed directly on the display panel 100, and in some cases, may be integrally disposed on the display panel 100. In addition, each source driver integrated circuits (SDIC) may be implemented by a COF method, and in this case, each source driver integrated circuit (SDIC) may be mounted on the film connected to the display panel 100 and electrically connected to the display panel 100 through lines on the film.

The controller 400 supplies various control signals to the gate driving circuit 200 and the data driving circuit 300 and controls the operation of the gate driving circuit 200 and the data driving circuit 300.

The controller 400 may be mounted on a printed circuit board, a flexible printed circuit, etc., and electrically connected to the data driving circuit 300 and the gate driving circuit 200 through the printed circuit board, the flexible printed circuit, etc.

The controller 400 controls the gate driving circuit 200 to output the scan signal according to the timing implemented in each frame, converts the image data received from the outside according to a data signal format used in the data driving circuit 300, and outputs the converted image data to the data driving circuit 300.

The controller 400 receives various timing signals including a vertical synchronization signal (VSYNC), a horizontal synchronization signal (HSYNC), an input data enable signal (DE), a clock signal (CLK), etc., along with the image data from an external source (e.g., a host system).

The controller 400 may generate various control signals using various timing signals received from the outside and output the generated control signals to the gate driving circuit 200 and the data driving circuit 300.

For example, to control the gate driving circuit 200, the controller 400 outputs various gate control signals GCS including a gate start pulse (GSP), a gate shift clock (GSC), a gate output enable signal (GOE), etc.

Here, the gate start pulse (GSP) controls the operation start timing of one or more gate driver integrated circuits (GDIC) that constitute the gate driving circuit 200. The gate shift clock (GSC) is a clock signal input in common to the one or more gate driver integrated circuits (GDIC) and controls the shift timing of the scan signal. The gate output enable signal (GOE) specifies the timing information of the one or more gate driver integrated circuits (GDIC).

In addition, to control the data driving circuit 300, the controller 400 outputs various data control signals DCS including a source start pulse (SSP), a source sampling clock (SSC), a source output enable signal (SOE), etc.

Here, the source start pulse (SSP) controls the data sampling start timing of one or more source driver integrated circuits (SDIC) that constitute the data driving circuit 300. The source sampling clock (SSC) is a clock signal for controlling the sampling timing of data in each source driver integrated circuit (SDIC). The source output enable signal (SOE) controls the output timing of the data driving circuit 300.

The display apparatus 1 may further include a power management integrated circuit (not illustrated) for supplying various voltages or currents to the display panel 100, the gate driving circuit 200, the data driving circuit 300, etc. or controlling various voltages or currents, which will be supplied.

Each sub-pixel SP is defined by the intersection of the gate line GL and the data line DL, and a liquid crystal or a light-emitting element EL may be disposed according to the type of the display apparatus 1.

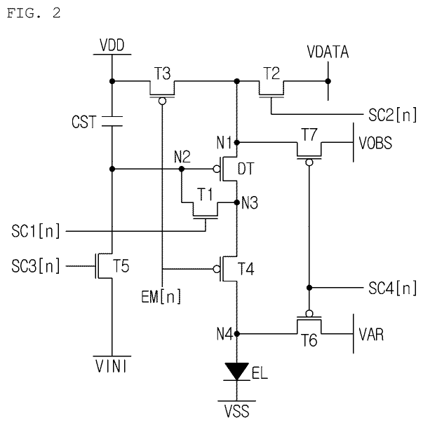

FIG. 2 is a circuit diagram of a sub-pixel according to an embodiment of the present disclosure.

Referring to FIGS. 1 and 2, the display apparatus 1 according to the embodiment of the present disclosure may include a plurality of sub-pixels SP. Each of the plurality of sub-pixels SP may include a plurality of thin film transistors. The plurality of thin film transistors may include a driving transistor and a switching transistor.

The embodiments of the present specification are not limited thereto, but the switching transistors are provided as a plurality of switching transistors, and at least one of the plurality of switching transistors may be formed as an oxide semiconductor transistor. In addition, the driving transistor may be formed as a low-temperature polycrystalline silicon (LTPS) transistor. However, the embodiments of the present specification are not limited thereto, and a multi-type thin film transistor may be configured in various ways. In addition, a pixel circuit in the display apparatus 1 may not include the multi-type thin film transistor but may include a thin film transistor of one type.

The pixel circuit illustrated in FIG. 2 is a pixel circuit disposed in an n^{th} row among a plurality of pixel circuits disposed in a matrix form on the display panel 100.

The pixel circuit according to the embodiment is composed of eight transistors and one capacitor. A first transistor T1, a second transistor T2, and a fifth transistor T5 may be formed as oxide semiconductor transistors that use an oxide semiconductor material as an active layer.

The plurality of switching transistors may include first to seventh transistors T1 to T7. The first to seventh transistors T1 to T7 may receive scan signals and a light-emitting control signal from the gate lines of the same row.

For example, in the pixel circuit disposed in the n^{th} row illustrated in FIG. 2, the first to seventh transistors T1 to T7 may receive scan signals SC1[n], SC2[n], SC3[n], and SC4[n] and a light-emitting control signal EM[n] from the gate lines of the n^{th} row.

The driving transistor DT supplies a driving current to the light-emitting element EL. The driving transistor DT includes a first electrode connected to a first node N1, a gate electrode connected to a second node N2, and a second electrode connected to a third node N3.

The first transistor T1 includes a first electrode connected to the second node N2, a second electrode connected to the third node N3, and a gate electrode connected to a first scan signal SC1[n]. The first transistor T1 is turned on when the first scan signal SC1[n] is high and electrically connects the second node N2 to the third node N3.

A second transistor T2 includes a first electrode connected to the first node N1, a second electrode connected to a data voltage VDATA, and a gate electrode connected to a second scan signal SC2[n]. The second transistor T2 is turned on when the second scan signal SC2[n] is high and supplies the data voltage VDATA to the first node N1.

That is, the second scan signal SC2[n] different from the first scan signal SC1[n] applied to the gate electrode of the first transistor T1 may be applied to the gate electrode of the second transistor T2.

A third transistor T3 includes a first electrode connected to a high-potential power voltage VDD, a second electrode connected to the first node N1, and a gate electrode connected to the light-emitting control signal EM[n]. The third transistor T3 is turned on when the light-emitting control signal EM[n] is low and supplies the high-potential power voltage VDD to the first node N1.

A fourth transistor T4 includes a first electrode connected to the third node N3, a second electrode connected to a fourth node N4, and a gate electrode connected to the light-emitting control signal EM[n]. The fourth transistor T4 is turned on when the light-emitting control signal EM[n] is low and electrically connects the third node N3 to the fourth node N4.

A fifth transistor T5 includes a first electrode connected to the second node N2, a second electrode connected to an initialization voltage VINI, and a gate electrode connected to a third scan signal SC3[n]. The fifth transistor T5 is turned on when the third scan signal SC3[n] is high and supplies the initialization voltage VINI to the second node N2.

That is, a third scan signal SC3[n] different from the first scan signal SC1[n] applied to the gate electrode of the first transistor T1 may be applied to the gate electrode of the fifth transistor T5.

A sixth transistor T6 includes a first electrode connected to an anode reset voltage VAR, a second electrode connected to the fourth node N4, and a gate electrode connected to a fourth scan signal SC4[n]. The sixth transistor T6 is turned on when the fourth scan signal SC4[n] is low and supplies the anode reset voltage VAR to the fourth node N4.

The seventh transistor T7 includes a first electrode connected to a bias voltage VOBS, a second electrode connected to the first node N1, and a gate electrode connected to the fourth scan signal SC4[n]. A seventh transistor T7 is turned on when the fourth scan signal SC4[n] is low and supplies the bias voltage VOBS to the first node N1.

The light-emitting element EL includes an anode electrode connected to the fourth node N4 and a cathode electrode connected to a low-potential power voltage VSS. The light-emitting element EL receives a driving current from the driving transistor DT and emits light.

A storage capacitor CST is connected between a high-potential power voltage source for applying the high-potential power voltage VDD and the second node N2. The storage capacitor CST maintains the data voltage VDATA signal in a pixel.

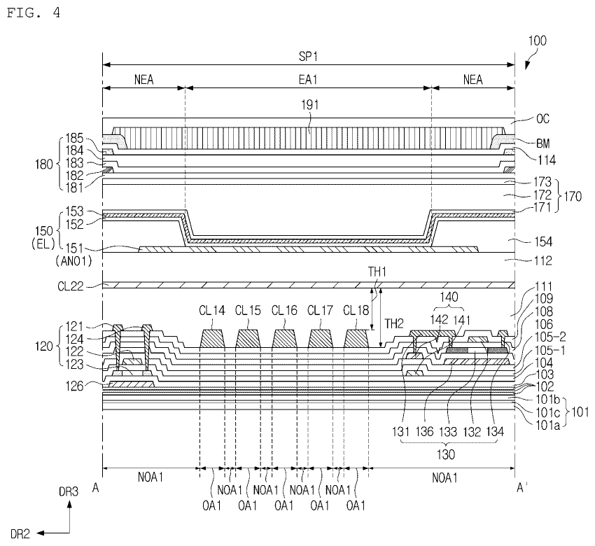

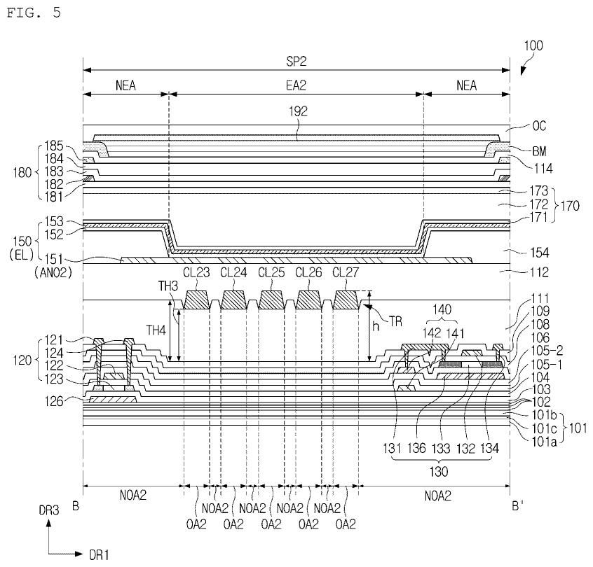

FIG. 3 illustrates a flat surface structure of a display panel according to one embodiment. FIG. 4 is a cross-sectional view taken along line A-A′ in FIG. 3. FIG. 5 is a cross-sectional view taken along line B-B′ in FIG. 3.

Referring to FIGS. 3 to 5, the display panel 100 may include a plurality of sub-pixels SP (SP1, SP2, and SP3). The plurality of sub-pixels SP may include a first sub-pixel SP1, a second sub-pixel SP2, and a third sub-pixel SP3.

The first sub-pixel SP1, the second sub-pixel SP2, and the third sub-pixel SP3 may form one pixel PX, and the display panel 100 may include a plurality of pixels PX. The plurality of pixels PX may be repeatedly disposed in the first direction DR1 and the second direction DR2.

The first sub-pixel SP1 and the third sub-pixel SP3 may be alternately disposed repeatedly in the second direction DR2. The second sub-pixel SP2 may be disposed in a direction between the first direction DR1 and the second direction DR2 (i.e., a line connecting the second sub-pixel SP2 and the first sub-pixel SP1 and a line connecting the second sub-pixel SP2 and the third sub-pixel SP3 each is neither parallel with the first direction DR1 nor parallel with the second direction DR2). The second sub-pixel SP2 may be repeatedly disposed in the second direction DR2.

The plurality of sub-pixels may include a red sub-pixel (Red SP) (or the first sub-pixel SP1) that emits red light, a blue sub-pixel (Blue SP) (or the second sub-pixel SP2) that emits blue light, and a green sub-pixel (Green SP) (or the third sub-pixel SP3) that emits green light.

In FIG. 3, the flat surface shapes of the plurality of sub-pixels SP1, SP2, and SP3 are exemplified as a circle, but the embodiments of the present specification are not limited thereto, and the flat surface shapes of the plurality of sub-pixels SP1, SP2, and SP3 may be diverse, such as a polygon, such as a quadrangle, etc. or an oval, etc.

Each of the sub-pixels SP1, SP2, and SP3 may include the light-emitting area EA. The light-emitting area EA may include a plurality of light-emitting areas EA1, EA2, and EA3. The light-emitting areas EA1, EA2, and EA3 may be disposed in the sub-pixels SP1, SP2, and SP3, respectively. That is, the first sub-pixel SP1 may include a first light-emitting area EA1, the second sub-pixel SP2 may include a second light-emitting area EA2, and the third sub-pixel SP3 may include a third light-emitting area EA3.

A pixel of the display panel 100 may include the plurality of sub-pixels SP1, SP2, and SP3. The first sub-pixel SP1 may be a red sub-pixel, the second sub-pixel SP2 may be a blue sub-pixel, and the third sub pixel SP3 may be a green sub-pixel, but the embodiments of the present specification are not limited thereto. In some embodiments, the pixel may further include a fourth sub-pixel, and the fourth sub-pixel may be a white sub-pixel, but the embodiments of the present specification are not limited thereto.

The display panel 100 may include a first circuit line CL1 extending in the first direction DR1 and a second circuit line CL2 extending in the second direction DR2. The pixel PX and the sub-pixels SP1, SP2, and SP3 may be disposed in an area in which the first circuit line CL1 and the second circuit line CL2 intersect each other.

The first circuit line CL1 may be disposed under a first protective layer 111 and covered by the first protective layer 111. The first circuit line CL1 may be disposed between the first protective layer 111 and a sixth insulating layer 109.

The first circuit line CL1 may include an 11^{th} circuit line CL11, a 12^{th} circuit line CL12, a 13^{th} circuit line CL13, a 14^{th} circuit line CL14, a 15^{th} circuit line CL15, a 16^{th} circuit line CL16, a 17^{th} circuit line CL17, an 18^{th} circuit line CL18, and a 19^{th} circuit line CL19. The 11^{th} to 19^{th} circuit lines CL11 to CL19 may be alternately and repeatedly disposed in the second direction DR2.

The first circuit line CL1 may include a first scan line that transmits the first scan signal SC1[n], a second scan line that transmits the second scan signal SC2[n], a third scan line that transmits the third scan signal SC3[n], a fourth scan line that transmits the fourth scan signal SC4[n], a bias line that transmits the bias voltage VOBS, an initialization line that transmits the initialization voltage VINI, a light-emitting control line that transmits the light-emitting control signal EM[n], etc. of FIG. 2.

That is, each of the 11^{th} to 19^{th} circuit lines CL11 to CL19 may be formed as one of the first scan line that transmits the first scan signal SC1[n], the second scan line that transmits the second scan signal SC2[n], the third scan line that transmits the third scan signal SC3[n], the fourth scan line that transmits the fourth scan signal SC4[n], the bias line that transmits the bias voltage VOBS, the initialization line that transmits the initialization voltage VINI, and the light-emitting control line that transmits the light-emitting control signal EM[n].

The second circuit line CL2 may be disposed on a different layer from the first circuit line CL1. The second circuit line CL2 may be disposed between the first protective layer 111 and a second protective layer 112 and covered by the second protective layer 112.

The second circuit line CL2 may include a 21^{st} circuit line CL21, a 22^{nd} circuit line CL22, a 23^{rd} circuit line CL23, a 24^{th} circuit line CL24, a 25^{th} circuit line CL25, a 26^{th} circuit line CL26, and a 27^{th} circuit line CL27. The 21^{th} to 27^{th} circuit lines CL21 to CL27 may be alternately disposed repeatedly in the first direction DR1.

The second circuit line CL2 may include the data line that transmits the data voltage VDATA, a high-potential power line that transmits the high-potential power voltage VDD, the anode reset line that transmits the anode reset voltage VAR, a low-potential power line that transmits the low-potential power voltage VSS, etc. in FIG. 2.

That is, each of the 21^{st} to 27^{th} circuit lines CL21 to CL27 may be formed as one of the data line that transmits the data voltage VDATA, the high-potential power line that transmits the high-potential power voltage VDD, the anode reset line that transmits the anode reset voltage VAR, and the low-potential power line that transmits the low-potential power voltage VSS in FIG. 2.

Hereinafter, a cross-sectional structure of the first sub-pixel SP1 of FIG. 4 will be described.

The display panel 100 may include the substrate 101, the first thin film transistor 120, the second thin film transistor 130, the storage capacitor 140, a light-emitting part 150, an encapsulation part 170, a touch part 180, a filter insulating layer 114, a black matrix BM, color filters 191 and 192, and a planarization layer OC. Here, the light-emitting part 150 may correspond to the light-emitting element EL of FIG. 2.

The display panel 100 may include at least one panel insulating layer and at least one touch insulating layer between the substrate 101 and the light-emitting part 150. The at least one panel insulating layer may include at least one of a buffer layer 102, a first insulating layer 103, a second insulating layer 104, a 3-1 insulating layer 105-1, a 3-2 insulating layer 105-2, a fourth insulating layer 106, a fifth insulating layer 108, a sixth insulating layer 109, a first protective layer 111, and a second protective layer 112, and the at least one touch insulating layer may include at least one of a touch buffer layer 181, a first touch insulating layer 183, and a second touch insulating layer 184.

The substrate 101 may include one or more plastic materials. For example, the substrate 101 may be a multi-substrate including a plurality of plastic materials, such as polyimide, etc. For example, the substrate 101 may include a first substrate portion 101a and a second substrate portion 101b each including a plastic material, and a third substrate portion 101c including an inorganic insulation material between the first substrate portion 101a and the second substrate portion 101b, but the embodiments of the present specification are not limited thereto.

A buffer layer 102 may be disposed on the substrate 101. The buffer layer 102 can minimize or delay the diffusion of moisture or oxygen penetrating the substrate 101. The buffer layer 102 may be formed by alternately stacking silicon nitride (SiNₓ) and silicon oxide (SiOₓ) at least once, but the embodiments of the present specification are not limited thereto.

A first light-blocking layer 126 may be disposed on the buffer layer 102. The first light-blocking layer 126 can prevent light from transmitting a first semiconductor layer 123 of the first thin film transistor 120. For example, the first semiconductor layer 123 may be disposed to overlap the first light-blocking layer 126. The first light-blocking layer 126 may be formed of a single layer or multiple layers formed of one or more of molybdenum (Mo), aluminum (Al), chromium (Cr), nickel (Ni), neodymium (Nd), and copper (Cu) and an alloy thereof, but the embodiments of the present specification are not limited thereto.

The first insulating layer 103 may be disposed on the buffer layer 102 and the first light-blocking layer 126. The first insulating layer 103 can prevent a short circuit between a component of the first thin film transistor 120 and the first light-blocking layer 126. The first insulating layer 103 may be formed of the same material as the buffer layer 102, but the embodiments of the present specification are not limited thereto. For example, the first insulating layer 103 may be formed of an inorganic insulation material, such as silicon nitride (SiNₓ) or silicon oxide (SiOₓ), but the embodiments of the present specification are not limited thereto.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include a metal oxide semiconductor, such as indium-gallium-zinc oxide (IGZO), and a silicon-based semiconductor material, such as amorphous silicon, polycrystalline silicon, etc., but the embodiments of the present specification are not limited thereto. The first semiconductor layer 123 may include a channel area, a source area, and a drain area.

Since the polycrystalline semiconductor layer has higher mobility than the amorphous semiconductor layer and the oxide semiconductor layer, power consumption can be less, and reliability can be excellent. Accordingly, a driving transistor may be formed of the polycrystalline semiconductor layer.

The second insulating layer 104 may be disposed on the first semiconductor layer 123. The second insulating layer 104 may be formed of the same material as the first insulating layer 103 and can prevent a short circuit between the first semiconductor layer 123 and another component of the first thin film transistor 120.

The first gate electrode 122 may be disposed on the second insulating layer 104. The first gate electrode 122 may be disposed on the second insulating layer 104 to overlap the channel area of the first semiconductor layer 123. The first gate electrode 122 may be formed of a single layer or multiple layers formed of one or more of molybdenum (Mo), copper (Cu), titanium (Ti), aluminum (Al), chromium (Cr), gold (Au), nickel (Ni), neodymium (Nd), and a compound thereof, but the embodiments of the present specification are not limited thereto. The first gate electrode 122 may be disposed along with a gate line.

The third insulating layers 105-1 and 105-2 may be disposed on the first gate electrode 122. The third insulating layers 105-1 and 105-2 may be formed by alternately stacking silicon nitride (SiNₓ) and silicon oxide (SiOₓ) at least once, but the embodiments of the present specification are not limited thereto. For example, the 3-1 insulating layer 105-1 may include silicon oxide (SiOₓ), and the 3-2 insulating layer 105-2 may include silicon nitride (SiNₓ), but the embodiments of the present specification are not limited thereto.

The first source electrode 121 and the first drain electrode 124 may be disposed on the third insulating layers 105-1 and 105-2.

The first source electrode 121 and the first drain electrode 124 may be electrically connected to the first semiconductor layer 123 through contact holes. The first source electrode 121 and the first drain electrode 124 may be formed of a metallic material. For example, the first source electrode 121 and the first drain electrode 124 may be formed of a single layer or multiple layers formed of one or more of molybdenum (Mo), aluminum (Al), chromium (Cr), gold (Au), titanium (Ti), nickel (Ni), neodymium (Nd), and copper (Cu) and an alloy thereof, but the embodiments of the present specification are not limited thereto.

The first source electrode 121 and the first drain electrode 124 may be disposed along with a data line. For example, the data line may be formed of the same material as the first source electrode 121 and the first drain electrode 124 and formed on the same layer as the first source electrode 121 and the first drain electrode 124, but the embodiments of the present specification are not limited thereto.

The storage capacitor 140 may be disposed to be spaced apart from the first thin film transistor 120. The storage capacitor 140 may include a first storage electrode 141 and a second storage electrode 142.

The first storage electrode 141 may be formed of the same material as the first gate electrode 122 and disposed on the same layer as the first gate electrode 122, but the embodiments of the present specification are not limited thereto.

The second storage electrode 142 may be disposed on the first storage electrode 141. The second storage electrode 142 may be disposed on the third insulating layers 105-1 and 105-2, and the third insulating layers 105-1 and 105-2 between the first storage electrode 141 and the second storage electrode 142 may be used as a dielectric to generate a capacitance. The second storage electrode 142 may be formed of the same material as the first storage electrode 141, but the embodiments of the present specification are not limited thereto.

The second thin film transistor 130 may be disposed to be spaced apart from the first thin film transistor 120 and the storage capacitor 140. The second thin film transistor 130 may include a second source electrode 131, a second gate electrode 132, a second semiconductor layer 133, and a second drain electrode 134.

A second light-blocking layer 136 may be disposed on the same layer as the second storage electrode 142.

The second light-blocking layer 136 can prevent light from traveling to the second semiconductor layer 133 similar to the first light-blocking layer 126, thereby extending the life of the second thin film transistor 130. For example, the second semiconductor layer 133 may be disposed to overlap the second light-blocking layer 136.

The fourth insulating layer 106 may be disposed on the second light-blocking layer 136. The fourth insulating layer 106 may be formed of the same material as the first insulating layer 103, the second insulating layer 104, or the third insulating layers 105-1 and 105-2, but the embodiments of the present specification are not limited thereto.

The second semiconductor layer 133 may be disposed on the fourth insulating layer 106. The second semiconductor layer 133 may include a source area, a drain area, and a channel area between the source area and the drain area.

The second semiconductor layer 133 may include a metal oxide semiconductor, such as indium-gallium-zinc oxide (IGZO), and a silicon-based semiconductor material, such as amorphous silicon, polycrystalline silicon, etc., but the embodiments of the present specification are not limited thereto.

The fifth insulating layer 108 may be disposed on the second semiconductor layer 133. The fifth insulating layer 108 may be formed of the same material as the first insulating layer 103, the second insulating layer 104, the third insulating layers 105-1 and 105-2, or the fourth insulating layer 106, but the embodiments of the present specification are not limited thereto.

The second gate electrode 132 may be disposed on the fifth insulating layer 108. The second gate electrode 132 may be formed of the same material as the first gate electrode 122. For example, the second gate electrode 132 may be formed of a single layer or multiple layers formed of one or more of molybdenum (Mo), copper (Cu), titanium (Ti), aluminum (Al), chromium (Cr), gold (Au), nickel (Ni), neodymium (Nd), and a compound thereof, but the embodiments of the present specification are not limited thereto.

The sixth insulating layer 109 may be disposed on the second gate electrode 132. The sixth insulating layer 109 may be formed of the same material as the first insulating layer 103, the second insulating layer 104, the third insulating layers 105-1 and 105-2, the fourth insulating layer 106, or the fifth insulating layer 108, but the embodiments of the present specification are not limited thereto.

The first source electrode 121, the first drain electrode 124, the second source electrode 131, the second drain electrode 134, and the first circuit line CL1 may be disposed on the sixth insulating layer 109.

The second source electrode 131, the second drain electrode 134, and the first circuit line CL1 may be formed of the same material as the first source electrode 121 and the first drain electrode 124 and disposed on the same layer as the first source electrode 121 and the first drain electrode 124, but the embodiments of the present specification are not limited thereto. For example, the second source electrode 131, the second drain electrode 134, and the first circuit line CL1 may be a single layer or multiple layers formed of one or more of molybdenum (Mo), aluminum (Al), chromium (Cr), gold (Au), titanium (Ti), nickel (Ni), neodymium (Nd), and copper (Cu), and an alloy thereof, but the embodiments of the present specification are not limited thereto. For example, the second source electrode 131 may be electrically connected to the second storage electrode 142. The second source electrode 131 may pass through the sixth insulating layer 109, the fifth insulating layer 108, and the fourth insulating layer 106 and may be electrically connected to the second storage electrode 142.

The first thin film transistor 120 may be a driving transistor, and the second thin film transistor 130 may be a switching transistor, but the embodiments of the present specification are not limited thereto. The first thin film transistor 120 and the second thin film transistor 130 may be disposed between the substrate 101 and the first circuit line CL1.

The first protective layer 111 may be disposed on the first source electrode 121, the first drain electrode 124, the second source electrode 131, the second drain electrode 134, and the first circuit line CL1.

The first protective layer 111 may planarize upper portions of the first thin film transistor 120 and the second thin film transistor 130 and protect the first thin film transistor 120 and the second thin film transistor 130. The first protective layer 111 may be formed of an organic material. For example, the first protective layer 111 may be formed of an organic material including an acrylic resin, an epoxy resin, a phenolic resin, a polyamide resin, or a polyimide resin, but the embodiments of the present specification are not limited thereto.

The first protective layer 111 may include a first overlapping area OA1 in which the first protective layer 111 overlaps the first circuit line CL1 in a thickness direction (a third direction DR3), and a first non-overlapping area NOA1 in which the first protective layer 111 does not overlap the first circuit line CL1. A thickness TH1 of the first protective layer 111 in the first overlapping area OA1 may be smaller than a thickness TH2 of the first protective layer 111 in the first non-overlapping area NOA1.

In an area in which the first protective layer 111 overlaps a first anode electrode ANO1, the first protective layer 111 may have a different thickness, for example, the thickness TH1 of the first protective layer 111 in the first overlapping area OA1 may be smaller than the thickness TH2 of the first protective layer 111 in the first non-overlapping region NOA1.

Accordingly, an upper surface of the first protective layer 111 may be flat. Here, the upper surface of the first protective layer 111 may refer to a surface facing the second protective layer 112. Accordingly, the second protective layer 112 disposed on the first protective layer 111 may also be formed to be generally flat. Furthermore, the first anode electrode ANO1 disposed on the second protective layer 112 may also be formed to be flat, thereby improving the flatness of the first anode electrode ANO1 and suppressing or preventing defects of the display panel 100.

That is, the shape of the first anode electrode ANO1 can be more smoothly formed to a desired shape. In addition, it is also possible to increase a degree of freedom related to the design of the layout of the display panel 100.

By using a slit mask, a half-tone mask, etc., a part of the upper surface of the first protective layer 111 disposed in the first overlapping area OA1 may be etched to form the flat upper surface of the first protective layer 111.

The second circuit line CL2 may be disposed on the first protective layer 111. The second circuit line may be a single layer or multiple layers formed of, for example, one or more of molybdenum (Mo), aluminum (Al), chromium (Cr), gold (Au), titanium (Ti), nickel (Ni), neodymium (Nd), and copper (Cu), and an alloy thereof, but the embodiments of the present specification are not limited thereto.

The second protective layer 112 may be disposed on the second circuit line CL2. The second protective layer 112 may be formed of the same material as the first protective layer 111, but the embodiments of the present specification are not limited thereto.

In some embodiments, a third protective layer may be further disposed on an upper surface of the second protective layer 112, but the embodiments of the present specification are not limited thereto.

Although not illustrated, a connection electrode may be further disposed between the first protective layer 111 and the second protective layer 112.

The connection electrode may electrically connect the first thin film transistor 120 to the light-emitting part 150. The connection electrode may be formed of the same material as the first source electrode 121 and the first drain electrode 124, but the embodiments of the present specification are not limited thereto.

The connection electrode may be formed of a single layer or multiple layers formed of one or more of molybdenum (Mo), aluminum (Al), chromium (Cr), gold (Au), titanium (Ti), nickel (Ni), neodymium (Nd), and copper (Cu) and an alloy thereof, but the embodiments of the present specification are not limited thereto.

The light-emitting part 150 may be disposed on the second protective layer 112. The light-emitting part 150 may include a first electrode 151, an organic layer 152, and a second electrode 153. The embodiments of the present specification are not limited thereto, but the first electrode 151 may serve as an anode, and the second electrode 153 may serve a cathode.

The first electrode 151 may be disposed on the second protective layer 112. The first electrode 151 may be electrically connected to the connection electrode through a contact hole formed in the second protective layer 112 and electrically connected to the first thin film transistor 120.

The first electrode 151 may be a reflective electrode that reflects light, but the embodiments of the present specification are not limited thereto. The first electrode 151 may include a metallic material with high reflectance, such as a stacking structure (Ti/Al/Ti) of aluminum (Al) and titanium (Ti), a stacking structure (ITO/Al/ITO) of aluminum (Al) and indium tin oxide (ITO), or an APC alloy and may be formed of a single layer or multiple layers, but the embodiments of the present specification are not limited thereto.

The first electrode 151 may include the first anode electrode ANO1 disposed in the first sub-pixel SP1, a second anode electrode ANO2 disposed in the second sub-pixel SP2, and a third anode electrode ANO3 disposed in the third sub-pixel SP3.

The organic layer 152 may be disposed on the first electrode 151. The organic layer 152 may include one or more light-emitting structures (or light-emitting elements or parts) stacked on the first electrode 151 in the order or reverse order of a hole transfer layer and an electron transfer layer.

For example, the hole transfer layer may include a hole transporting layer, a hole injecting layer, an electron blocking layer, a p-type charge generation layer, etc., but the embodiments of the present specification are not limited thereto. For example, the electron transfer layer may include an electron transporting layer, an electron injecting layer, a hole blocking layer, an n-type charge generation layer, etc., but the embodiments of the present specification are not limited thereto.

The organic layer 152 may be an organic light-emitting layer, an inorganic light-emitting layer, a quantum dot light-emitting layer, a micro light-emitting diode, a micro mini light-emitting diode, etc., but the embodiments of the present specification area not limited thereto.

For example, the organic layer 152 of the display panel 100 according to one embodiment of the present specification may include an organic light-emitting layer. The organic layer 152 may include a red light-emitting layer, a green light-emitting layer, and a blue light-emitting layer. The organic layer 152 may be a white light-emitting layer, but the embodiments of the present specification are not limited thereto. Hereinafter, a specific structure of the organic layer 152 according to one embodiment will be described.

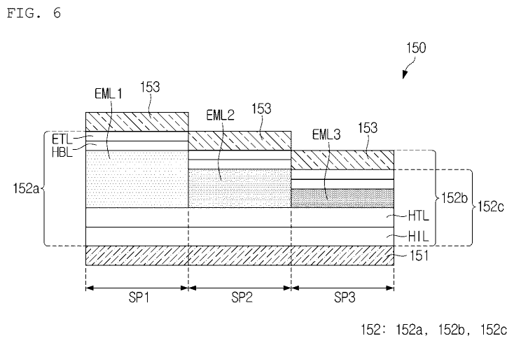

FIG. 6 is a specific cross-sectional view of a light-emitting part of FIG. 4.

Referring to FIG. 6, the light-emitting part 150 may be disposed across the first sub-pixel SP1, the second sub-pixel SP2, and the third sub-pixel SP3.

A thickness of the light-emitting part 150 in each sub-pixel SP1, SP2, or SP3 may be different, but the embodiments of the present specification are not limited thereto, and the thickness of the light-emitting part 150 in each sub-pixel SP1, SP2, or SP3 may be the same.

The organic layer 152 may include a first organic layer 152a disposed in the first sub-pixel SP1, a second organic layer 152b disposed in the second sub-pixel SP2, and a third organic layer 152c disposed in the third sub-pixel SP3. The light-emitting layers EML1, EML2, and EML3 of the organic layers 152a, 152b, and 152c may be physically separated, but lower layers and upper layers of the light-emitting layers EML1, EML2, and EML3 may be formed integrally across the sub-pixels SP1, SP2, and SP3. A thicknesses of each light-emitting layer EML1, EML2, or EML3 may be different. For example, a thickness of a first light-emitting layer EML1 may be the greatest, a thickness of a second light-emitting layer EML2 may be the second greatest, and a thickness of the third light-emitting layer EML3 may be the smallest, but the embodiments of the present specification are not limited thereto.

A hole injecting layer HIL may be disposed on the first electrode 151. The hole injecting layer HIL may be located between the first electrode 151 and the light-emitting layers EML1, EML2, and EML3. The hole injecting layer HIL may be formed integrally across the sub-pixels SP1, SP2, and SP3. For example, the hole injecting layer HIL may be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present specification are not limited thereto.

A hole transporting layer HTL may be disposed on the hole injecting layer HIL. The hole transporting layer HTL may be located between the hole injecting layer HIL and the light-emitting layers EML1, EML2, and EML3. The hole transporting layer HTL may be formed integrally across the sub-pixels SP1, SP2, and SP3. The hole transporting layer HTL may be formed of one or more selected from the group consisting of arylamine-based materials, such as NPB (N,N-naphthyl-N,N′-phenyl benzidine), TPD (N,N′-bis-(3-methylphenyl)-N,N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthyl-N,N′-diphenyl benzidine), s-TAD, and MTDATA(4,4′,4″-Tris(N-3-methylphenyl-N-phenyl-amino)-triphenylamine), but the embodiments of the present specification are not limited thereto.

The light-emitting layers EML1, EML2, and EML3 may be disposed on the hole transporting layer HTL. The first light-emitting layer EML1 may be disposed in the first sub-pixel SP1, the second light-emitting layer EML2 may be disposed in the second sub-pixel SP2, and the third light-emitting layer EML3 may be disposed in the third sub-pixel SP3.

A thicknesses of each light-emitting layer EML1, EML2, or EML3 may be different. For example, the first light-emitting layer EML1 may be formed in a thickness of 600 to 800 angstroms (10⁻¹⁰ meters), the second light-emitting layer EML2 may be formed in a thickness of 300 to 500 angstroms (10⁻¹⁰ meters), and the third light-emitting layer EML3 may be formed in a thickness of 100 to 300 angstroms (10⁻¹⁰ meters), but the embodiments of the present specification are not limited thereto.

Each of the first light-emitting layer EML1, the second light-emitting layer EML2, and the third light-emitting layer EML3 may include a material that may emit light in the visible light range by receiving and combining holes and electrons.

A hole blocking layer HBL may be disposed on each light-emitting layer EML1, EML2, or EML3. The hole blocking layer HBL may be disposed integrally across the sub-pixels SP1, SP2, and SP3.

An electron transporting layer ETL may be disposed on the hole blocking layer HBL. The electron transporting layer ETL may be disposed integrally across the sub-pixels SP1, SP2, and SP3. The electron transporting layer ETL may be formed of an anthracene derivative and lithium quinolate (Liq) or formed of one or more selected from oxadiazole, triazole, phenanthroline, benzoxazole, benzthiazole, and benzimidazole (e.g., 2-[4-(9,10-Di-2-naphthalenyl-2-anthracenyl)phenyl]-1-phenyl-1H-benzimidazole), but the embodiments of the present specification are not limited thereto.

The second electrode 153 may be disposed on the electron transporting layer ETL.

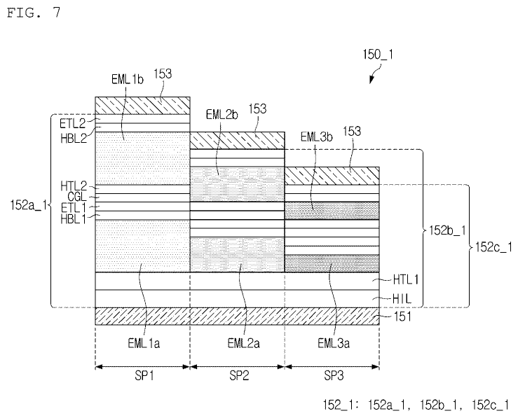

FIG. 7 is a specific cross-sectional view of a light-emitting part according to a modified example.

Referring to FIGS. 6 and 7, an organic layer 152_1 may include a first organic layer 152a_1 disposed in the first sub-pixel SP1, a second organic layer 152b_1 disposed in the second sub-pixel SP2, and a third organic layer 152c_1 disposed in the third sub-pixel SP3.

The light-emitting layers of each organic layer 152a_1, 152b_1, or 152c_1 may be physically separated, but the lower layers and upper layers of the light-emitting layers may be formed integrally across the sub-pixels SP1, SP2, and SP3. The thickness of each light-emitting layer may be different. For example, the thickness of the first light-emitting layer of the first sub-pixel may be the greatest, the thickness of the second light-emitting layer of the second sub-pixel may be the second greatest, and the thickness of the third light-emitting layer of the third sub-pixel may be the smallest, but the embodiments of the present specification are not limited thereto. In addition, the light-emitting layers of each organic layer 152a_1, 152b_1, or 152c_1 may be provided as two or more light-emitting layers.

A hole injecting layer HIL may be disposed on the first electrode 151. The hole injecting layer HIL may be located between the first electrode 151 and the light-emitting layers EML1a, EML2a, and EML3a. The hole injecting layer HIL may be formed integrally across the sub-pixels SP1, SP2, and SP3. For example, the hole injecting layer HIL may be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present specification are not limited thereto.

A first hole transporting layer HTL1 may be disposed on the hole injecting layer HIL. The first hole transporting layer HTL1 may be located between the hole injecting layer HIL and light-emitting layers EML1a, EML2a, and EML3a. The first hole transporting layer HTL1 may be formed integrally across the sub-pixels SP1, SP2, and SP3. The first hole transporting layer HTL1 may be formed of one or more selected from the group consisting of arylamine-based materials, such as NPB (N,N-naphthyl-N,N′-phenyl benzidine), TPD (N,N′-bis-(3-methylphenyl)-N,N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthyl-N,N′-diphenyl benzidine), s-TAD, and MTDATA(4,4′,4″ Tris(N-3-methylphenyl-N-phenyl-amino)-triphenylamine), but the embodiments of the present specification are not limited thereto.

The light-emitting layers EML1a, EML2a, and EML3a may be disposed on the first hole transporting layer HTL1. A 1-1 light-emitting layer EML1a may be disposed in the first sub-pixel SP1, a 2-1 light-emitting layer EML2a may be disposed in the second sub-pixel SP2, and a 3-1 light-emitting layer EML3a may be disposed in the third sub-pixel SP3. Each of the light-emitting layers EML1a, EML2a, and EML3a may be the same as each of the light-emitting layers EML1, EML2, and EML3 of FIG. 6.

A thicknesses of each light-emitting layer EML1a, EML2a, or EML3a may be different. For example, the 1-1 light-emitting layer EML1a may be formed in a thickness of 600 to 800 angstroms (10⁻¹⁰ meters), the 2-1 light-emitting layer EML2a may be formed in a thickness of 300 to 500 angstroms (10⁻¹⁰ meters), and the 3-1 light-emitting layer EML3a may be formed in a thickness of 100 to 300 angstroms (10⁻¹⁰ meters), but the embodiments of the present specification are not limited thereto.

A first hole blocking layer HBL1 may be disposed on each light-emitting layer EML1a, EML2a, or EML3a. The first hole blocking layer HBL1 may be formed integrally across the sub-pixels SP1, SP2, and SP3.

A first electron transporting layer ETL1 may be disposed on the first hole blocking layer HBL1. The first electron transporting layer ETL1 may be formed integrally across the sub-pixels SP1, SP2, and SP3. The first electron transporting layer ETL1 may be formed of an anthracene derivative and lithium quinolate (Liq) or formed of one or more selected from oxadiazole, triazole, phenanthroline, benzoxazole, benzthiazole, and benzimidazole (e.g., 2-[4-(9,10-Di-2-naphthalenyl-2-anthracenyl)phenyl]-1-phenyl-1H-benzimidazole), but the embodiments of the present specification are not limited thereto.

A charge generation layer CGL may be disposed on the first electron transporting layer ETL1. The charge generation layer CGL may be disposed between the first electron transporting layer ETL1 and a second hole transporting layer HTL2. The charge generation layer CGL may include a conductive material, but the embodiments of the present disclosure are not limited thereto.

The second hole transporting layer HTL2 may be disposed on the charge generation layer CGL. The second hole transporting layer HTL2 may be disposed between the first hole blocking layer HBL1 and the light-emitting layers EML1b, EML2b, and EML3b. The second hole transporting layer HTL2 may be formed integrally across the sub-pixels SP1, SP2, and SP3. A material of the second hole transporting layer HTL2 may be the same as a material of the first hole transporting layer HTL1, but the embodiments of the present specification are not limited thereto.

The light-emitting layers EML1b, EML2b, and EML3b may be disposed on the second hole transporting layer HTL2. A 1-2 light-emitting layer EML1b may be disposed in the first sub-pixel SP1, a 2-2 light-emitting layer EML2b may be disposed in the second sub-pixel SP2, and a 3-2 light-emitting layer EML3b may be disposed in the third sub-pixel SP3. Each of the light-emitting layers EML1b, EML2b, and EML3b may be the same as each of the light-emitting layers EML1a, EML2a, and EML3a.

A thicknesses of each light-emitting layer EML1b, EML2b, or EML3b may be different. For example, the 1-2 light-emitting layer EML1b may be formed in a thickness of 600 to 800 angstroms (10⁻¹⁰ meters), the 2-2 light-emitting layer EML2 b may be formed in a thickness of 300 to 500 angstroms (10⁻¹⁰ meters), and the 3-2 light-emitting layer EML3 b may be formed in a thickness of 100 to 300 angstroms (10⁻¹⁰ meters), but the embodiments of the present specification are not limited thereto.

A second hole blocking layer HBL2 may be disposed on each light-emitting layer EML1b, EML2b, or EML3b. The second hole blocking layer HBL2 may be formed integrally across the sub-pixels SP1, SP2, and SP3.

A second electron transporting layer ETL2 may be disposed on the second hole blocking layer HBL2. The second electron transporting layer ETL2 may be formed integrally across the sub-pixels SP1, SP2, and SP3. The second electron transporting layer ETL2 may be formed of an anthracene derivative and lithium quinolate (Liq) or formed of one or more selected from oxadiazole, triazole, phenanthroline, benzoxazole, benzthiazole, and benzimidazole (e.g., 2-[4-(9,10-Di-2-naphthalenyl-2-anthracenyl)phenyl]-1-phenyl-1H-benzimidazole), but the embodiments of the present specification are not limited thereto.

The second electrode 153 may be disposed on the second electron transporting layer ETL2.

Referring back to FIG. 4, the second electrode 153 may be disposed on the organic layer 152. The second electrode 153 may be a transparent electrode that transmits light, but the embodiments of the present specification are not limited thereto. For example, the second electrode 153 may include a transparent conductive material, such as indium tin oxide (ITO) or indium zinc oxide (IZO), or a metal that transmits visible light, but the embodiments of the present specification are not limited thereto.

A bank 154 may be disposed to expose the first electrode 151. The bank 154 may be disposed to define the light-emitting area EA (EA1, EA2, and EA3) of the sub-pixels SP1, SP2, and SP3 and cover an edge portion (or a periphery) of the first electrode 151.

The non-light-emitting area NEA may be disposed around the light-emitting area EA. The bank 154 may be disposed in the non-light-emitting area NEA.

The light-emitting area EA may include the first light-emitting area EA1, the second light-emitting area EA2, and the third light-emitting area EA3 that are disposed in the sub-pixels SP1, SP2, and SP3, respectively. The non-light-emitting area NEA may be disposed around each light-emitting area EA1, EA2, or EA3. The non-light-emitting area NEA may correspond to boundaries of adjacent sub-pixels SP1, SP2, and SP3.

The bank 154 may be formed of an organic material, such as a benzocyclobutene resin, a polyimide resin, an acrylic resin, a photosensitive polymer, etc. However, the embodiments of the present specification are not limited thereto, and the bank 154 may further include a black-based material. For example, the bank 154 may be formed of a material containing black pigment, or an organic material, such as a benzocyclobutene resin, a polyimide resin, an acrylic resin, a photosensitive polymer, etc., but the embodiments of the present specification are not limited thereto. When the bank 154 is formed of a material containing black pigment or black dye, the bank 154 may be an opaque bank. When the bank 154 is formed of a material containing black pigment or black dye, it is possible to block external light or light reflected from the outside, thereby further increasing the luminance of the display apparatus.

The organic layer 152 may be disposed on the first electrode 151. The second electrode 153 may be disposed on the organic layer 152.

The encapsulation part 170 may be disposed on the second electrode 153. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic insulation material layers and one or more organic material layers. For example, the first encapsulation layer 171 and the third encapsulation layer 173 may include an inorganic insulation material, and the second encapsulation layer 172 may include an organic material, but the embodiments of the present specification are not limited thereto.

The touch part 180 may be disposed on the encapsulation part 170. The touch part 180 may include the touch buffer layer 181, a first touch conductive layer, the first touch insulating layer 183, the second touch insulating layer 184, and a second touch conductive layer. In some embodiments, one or more touch organic layers may be further disposed on the second touch conductive layer, but the embodiments of the present specification are not limited thereto.

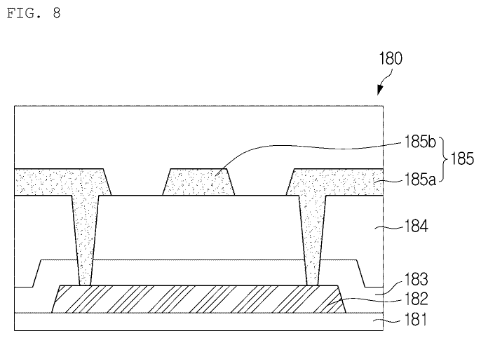

FIG. 8 is a cross-sectional view of a touch part according to FIG. 4.

Referring to FIGS. 4 and 8, the touch buffer layer 181 may be disposed on the encapsulation part 170. For example, a touch buffer layer 181 may be disposed on the third encapsulation layer 173. The touch buffer layer 181 may be formed of the same material as the buffer layer 102, but the embodiments of the present specification are not limited thereto.

The first touch conductive layer may be disposed on the touch buffer layer 181. The first touch conductive layer may include a bridge electrode 182. The bridge electrode 182 and a sensor electrode 185 to be described below may be disposed at each of the boundaries between adjacent sub-pixels SP1, SP2, and SP3. For example, the bridge electrode 182 and the sensor electrode 185 may be disposed in the non-light-emitting areas NEA. The bridge electrode 182 and the sensor electrode 185 may overlap the black matrix BM to be described below in the thickness direction. The black matrix BM may cover the bridge electrode 182 and the sensor electrode 185. Accordingly, the bridge electrode 182 and the sensor electrode 185 can be prevented from being visible from the outside.

The first touch insulating layer 183 and the second touch insulating layer 184 disposed on the first touch insulating layer 183 may be disposed on the first touch conductive layer. The first touch insulating layer 183 and the second touch insulating layer 184 disposed on the first touch insulating layer 183 can prevent a short circuit between the first touch conductive layer and the second touch conductive layer. The first touch insulating layer 183 may be formed of silicon oxide (SiOₓ), silicon nitride (SiNₓ), or multiple layers thereof, but the embodiments of the present specification are not limited thereto. The second touch insulating layer 184 may include an organic insulation material, but the embodiments of the present specification are not limited thereto, and the second touch insulating layer 184 may include the same material as the first touch insulating layer 183.

The second touch conductive layer may be disposed on the second touch insulating layer 184. The second touch conductive layer may include a first sensor electrode 185a and a second sensor electrode 185b. The sensor electrode 185 may include the first sensor electrode 185a extending in the first direction DR1 (see FIG. 3) and the second sensor electrode 185b extending in the second direction DR2 (see FIG. 3) different from the first direction DR1.

The bridge electrode 182 may be electrically connected to the first sensor electrode 185a through a contact hole formed in the first touch insulating layer 183 and the second touch insulating layer 184. For example, the first sensor electrode 185a and the bridge electrode 182 may extend in the first direction DR1 (see FIG. 3).

The sensor electrode 185 and the bridge electrode 182 may include a metallic material. For example, the sensor electrode 185 and the bridge electrode 182 may be formed of titanium (Ti), nickel (Ni), aluminum (Al), or an alloy thereof and formed of a triple layer, such as titanium (Ti)/aluminum (Al)/titanium (Ti), but the embodiments of the present specification are not limited thereto.

In the present embodiment, an example in which the touch part 180 is disposed directly on the encapsulation part 170 has been described, but the embodiments of the present specification are not limited thereto. For example, the touch part 180 may be disposed separately from the display panel 100 as a separate component, or a substrate and/or an insulating layer may be further disposed between the touch part 180 and the encapsulation part 170.

Referring back to FIG. 4, the filter insulating layer 114 may be disposed on the sensor electrode 185. The filter insulating layer 114 may be formed of an inorganic insulation material, such as silicon nitride (SiNₓ) or silicon oxide (SiOₓ), but the embodiments of the present specification are not limited thereto.

The black matrix BM may be disposed on the filter insulating layer 114. The black matrix BM may include a black-based material. For example, the black matrix BM may include a light-blocking material or a light-absorbing material. For example, the black matrix BM may be formed of a material including a black pigment, a black dye, etc. The black matrix BM may cover the bridge electrode 182 and the sensor electrode 185. Accordingly, the bridge electrode 182 and the sensor electrode 185 can be prevented from being visible from the outside. For example, a width of the black matrix BM may be smaller than a width of the bank 154.

For example, spacing distances between an end of the black matrix BM and boundaries between the light-emitting areas EA1, EA2, and EA3 and the non-light-emitting areas NEA may be longer than spacing distances between an end of the bank 154 and the boundaries between the light-emitting areas EA1, EA2, and EA3 and the non-light-emitting areas NEA. The end of the bank 154 may be aligned with the boundaries between the light-emitting areas EA1, EA2, and EA3 and the non-light-emitting areas NEA, but the embodiments of the present specification are not limited thereto. In the case of the display panel 100 according to one embodiment, since the bank 154 may include a black-based material and the spacing distances between the end of the black matrix BM and the boundaries between the light-emitting areas EA1, EA2, and EA3 and the non-light-emitting areas NEA may be longer than the spacing distances between the end of the bank 154 and the boundaries between the light-emitting areas EA1, EA2, and EA3 and the non-light-emitting areas NEA, light emitted from the light-emitting areas EA1, EA2, and EA3 may be emitted upward with wider viewing angles as much as spacing spaces between the end of the black matrix BM and the boundaries between the light-emitting areas EA1, EA2, and EA3 and the non-light-emitting areas NEA. Accordingly, it is possible to minimize a reduction in luminance according to a viewing angle. However, when the spacing distances between the end of the black matrix BM and the boundaries between the light-emitting areas EA1, EA2, and EA3 and the non-light-emitting areas NEA may be longer than the spacing distances between the end of the bank 154 and the boundaries between the light-emitting areas EA1, EA2, and EA3 and the non-light-emitting areas NEA and the bank 154 is formed of only a transparent material, externally incident light may be reflected by the bank 154, resulting in visible ring-shaped spots. However, in the case of the display panel 100 according to one embodiment, the light incident from the outside may be absorbed or blocked by the bank 154 including a black-based material, thereby preventing the occurrence of the ring-shaped spots.

The color filters 191 and 192 may be disposed on the black matrix BM. The color filters may be disposed on the first to third sub-pixels SP1, SP2, and SP3, respectively, and may block specific colors of light from light emitted from the light-emitting area EA1, EA2, and EA3 of the sub-pixels SP1, SP2, and SP3. A first color filter 191 may be provided to block light of other colors not including red (R) light. In this case, the first color filter 191 may be provided as a red color filter. The second color filter 192 may be provided to block light of other colors not including green (G) light. In this case, a second color filter 192 may be provided as a green color filter. A third color filter in the third sub-pixel SP3 may be provided to block light of other colors not including blue (B) light. In this case, the third color filter may be provided as a blue color filter. However, the embodiments of the present specification are not limited thereto.

For example, each color filter may come into direct contact with side and upper surfaces of the black matrix BM. For example, each color filter may be spaced apart from the boundaries of adjacent sub-pixels SP1, SP2, and SP3, but the embodiments of the present specification are not limited thereto, and the color filters may overlap each other in the thickness direction.

The planarization layer OC may be disposed on the color filters. The planarization layer OC may serve to planarize a step formed by the color filters. For example, the planarization layer OC may include an organic insulation material.

As described above, an example in which the black matrix BM and the color filters are disposed directly on the touch part 180 has been described, but the embodiments of the present specification are not limited thereto. For example, separate substrates and insulating layers may be additionally disposed between the black matrix BM and the color filters and the touch part 180, or an optical layer, etc. may be additionally disposed therebetween.

Hereinafter, a cross-sectional structure of the second sub-pixel SP2 of FIG. 5 will be described. For contents that are substantially the same among components included in the first sub-pixel SP1 of FIG. 4, the same reference numerals are given, and the overlapping contents may be omitted or briefly described.

The first protective layer 111 disposed in the second sub-pixel SP2 of FIG. 5 may include a different structure from the first protective layer 111 disposed in the first sub-pixel SP1 of FIG. 4.

In FIG. 5, the first protective layer 111 may include a second overlapping area OA2 in which the first protective layer 111 overlaps the second circuit line CL2 in the thickness direction (the third direction DR3), and a second non-overlapping area NOA2 in which the first protective layer 111 does not overlap the second circuit line CL2. A thickness TH3 of the first protective layer 111 in the second overlapping area OA2 may be smaller than a thickness TH4 of the first protective layer 111 in the second non-overlapping area NOA2.

In an area in which the first protective layer 111 overlaps the second anode electrode ANO2 in the thickness direction (the third direction DR3), the thickness TH3 of the first protective layer 111 in the second overlapping area OA2 may be smaller than the thickness TH4 of the second protective layer 111 in the second non-overlapping area NOA2.

The first protective layer 111 may define a plurality of trenches TR in the area in which the first protective layer 111 overlaps the second anode electrode ANO2. The trench TR may be formed by being recessed from the upper surface of the first protective layer 111 in the thickness direction (the third direction DR3). The plurality of trenches TR may be disposed in the second overlapping area OA2. The plurality of trenches TR may be disposed in the second overlapping area OA2 and may overlap the second anode electrode ANO2 in the thickness direction (the third direction DR3), but are not limited thereto. Alternatively, in an area in which the first protective layer 111 overlaps the first anode electrode ANO1, the first protective layer 111 may include a trench recessed in the thickness direction.

By using a slit mask, a half-tone mask, etc., a part of the upper surface of the first protective layer 111 disposed in the second overlapping area OA2 may be etched to form the trench TR.

The second circuit line CL2 may be disposed in the trench TR. The second circuit line CL2 disposed in the trench TR may be the second circuit line CL2 that overlaps the second anode electrode ANO2 in the thickness direction (the third direction DR3).

For example, at least parts of the 23^{rd} to 27^{th} circuit lines CL23 to CL27 of FIG. 5 may overlap the second anode electrode ANO2 in the thickness direction (the third direction DR3). The 23^{rd} to 27^{th} circuit lines CL23 to CL27 may be disposed in the trench TR. Portions of the 23^{rd} to 27^{th} circuit lines CL23 to CL27, which overlap the second anode electrode ANO2 in the thickness direction (the third direction DR3), may be disposed in the trench TR, but are not limited thereto.

The trenches TR may be recessed to the same depth, but are not limited thereto. The trenches TR may be recessed to different depths.

All heights h of an upper surface of the second circuit lines CL2 disposed in the trenches TR may be the same. To form the height h of the upper surface of the second circuit line CL2 at the same level, the depth of the trench TR may be adjusted in various ways. Here, the upper surface of the second circuit line CL2 may refer to the surface facing the second protective layer 112.

The upper surface of the second circuit line CL2 may protrude from the upper surface the first protective layer 111 toward the second protective layer 112. However, the embodiments of the present specification are not limited thereto, and in the area in which the second circuit line CL2 overlaps the second anode electrode ANO2 in the thickness direction (the third direction DR3), the height h of the upper surface of the second circuit line CL2 in the area may be the same as the height of the upper surface of the first protective layer 111.

Since the first protective layer 111 defines the trench TR and the second circuit line CL2 of which at least a part overlaps the second anode electrode ANO2 in the trench TR, the height h of the upper surface of the second circuit line CL2 may be reduced. That is, the height h of the upper surface of the second circuit line CL2 may be adjusted through the trench TR.

Accordingly, the upper surface of the first protective layer 111 may be flat. Here, the upper surface of the first protective layer 111 may refer to the surface facing the second protective layer 112. Accordingly, the second protective layer 112 disposed on the first protective layer 111 may also be formed to be generally flat. Furthermore, the second anode electrode ANO2 disposed on the second protective layer 112 may also be formed to be flat, thereby improving the flatness of the second anode electrode ANO2 and suppressing or preventing defects of the display panel 100.

The first overlapping area OA1 and the second overlapping area OA2 of FIG. 5 may overlap each other in the thickness direction (the third direction DR3) in some areas. In this case, in an area in which the first overlapping area OA1 and the second overlapping area OA2 overlap each other, the thickness of the first protective layer 111 may be smaller than each of the thickness TH1 of the first protective layer 111 of the first overlapping area OA1 and the thickness TH3 of the first protective layer 111 of the second overlapping area OA2, but is not limited thereto.

As described above, the cross-sectional structure of the first sub-pixel SP1 and the cross-sectional structure of the second sub-pixel SP2 have been described. The content that is substantially the same as the cross-sectional structure of the first sub-pixel SP1 or the content that is substantially the same as the cross-sectional structure of the second sub-pixel SP2 may be applied to the third sub-pixel SP3.

Hereinafter, other embodiments of the present specification will be described. For contents that are substantially the same as those described with reference to FIGS. 1 to 8 among components included in other embodiments, the same reference numerals are given, and overlapping contents may be omitted or briefly described.

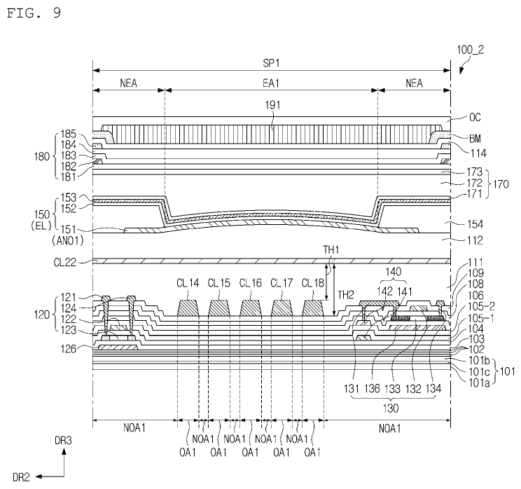

FIG. 9 is a cross-sectional view of a sub-pixel according to another embodiment.

Referring to FIG. 9, a display panel 100_2 of the display apparatus according to the present embodiment includes the first electrode 151 (see FIG. 3), and the first anode electrode ANO1 may have a convex shape in a direction in which light is emitted.

Specifically, the first anode electrode ANO1 of the first sub-pixel SP1 may have a convex shape in the direction in which light is emitted. The first anode electrode ANO1 is not limited thereto, but in the first light-emitting area EA1, the first anode electrode ANO1 may have a convex shape.

The second protective layer 112 may have a convex shape that protrudes toward the encapsulation part 170 or toward the first anode electrode ANO1 in an area that the second protective layer 112 overlaps the first anode electrode ANO1 in the thickness direction (the third direction DR3). The second protective layer 112 may have a convex shape that protrudes toward the encapsulation part 170 in an area in which the second protective layer 112 overlaps the first light-emitting area EA1 in the thickness direction (the third direction DR3).

Since the first anode electrode ANO1 disposed on the second protective layer 112 may be disposed to correspond to the curve of the upper surface of the second protective layer 112, the first anode electrode ANO1 may have a convex shape. That is, the first anode electrode ANO1 may have a convex shape corresponding to the convex shape of the second protective layer 112.

The convex shape of the second protective layer 112 may be formed using a slit mask, a half-tone mask, etc., but the method of forming the convex shape of the second protective layer 112 is not limited thereto and may be diverse.

Accordingly, the shape of the first anode electrode ANO1 can be formed to a desired shape more smoothly. In addition, it is also possible to increase a degree of freedom related to the design of the layout of the display panel 100.

Since the first anode electrode ANO1 has a convex shape in the direction in which light is emitted, it is possible to improve the color viewing angle characteristics and enable the low-power driving of the display apparatus, thereby reducing power consumption.

As described above, the first sub-pixel SP1 has been described as an example, but the description thereof may be applied to the second sub-pixel SP2 and the third sub-pixel SP3 in the same manner.

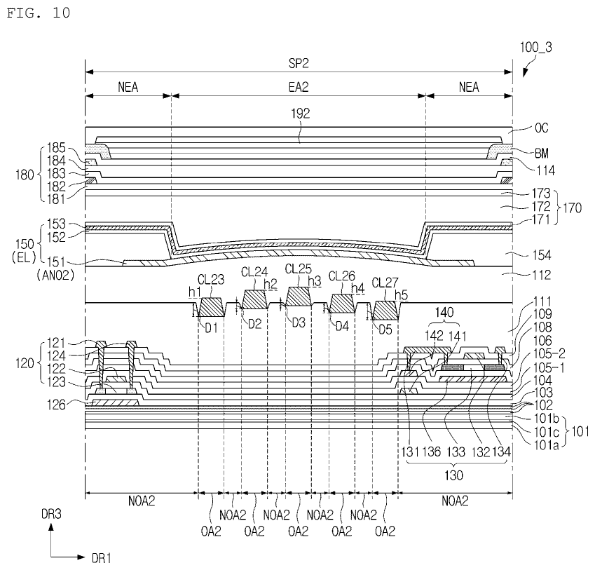

FIG. 10 is a cross-sectional view of a sub-pixel according to still another embodiment.

Referring to FIG. 10, in a display panel 100_3 of the display apparatus according to the present embodiment, the trenches TR may have different depths D1, D2, D3, D4, and D5. Here, the depths D1, D2, D3, D4, and D5 of the trenches TR may refer to the degree (depth) of being recessed from the upper surface to the lower surface of the first protective layer 111.

For example, in the second sub-pixel SP2, in an area overlapping the second anode electrode ANO2, the trenches TR may include first to fifth trenches TR1 to TR5. The 23^{rd} to 27^{th} circuit lines CL23 to CL27 may be disposed in the first to fifth trenches TR1 to TR5, respectively.

In the area in which the trench TR overlaps the second anode electrode ANO2 in the thickness direction (the third direction DR3), the recessed depths of at least some of the trenches TR may be different.

For example, in the area in which the trench TR overlaps the second anode electrode ANO2, the recessed depth of the trench TR may be greater from the periphery of a central portion of the second anode electrode ANO2 toward one side and/or the other side in the first direction DR1.

In FIG. 10, the depth D3 of a third trench TR3 may be smaller than the depth D2 of a second trench TR2 and the depth D4 of a fourth trench TR4, the depth D2 of the second trench TR2 may be smaller than the depth D1 of a first trench TR1, and the depth D4 of the fourth trench TR4 may be smaller than the depth D5 of a fifth trench TR5.

In the area in which the second circuit line CL2 overlaps the second anode electrode ANO2 in the thickness direction (the third direction DR3), the height of the upper surface of the second circuit line CL2 (see FIG. 3) may be different.

For example, in the area in which the second circuit line CL2 overlaps the second anode electrode ANO2, the height of the upper surface of the second circuit line CL2 (see FIG. 3) may decrease from the periphery of the central portion of the second anode electrode ANO2 toward one side and/or the other side in the first direction DR1.

In FIG. 10, a height h3 of the 25^{th} circuit line CL25 may be higher than a height h2 of the 24^{th} circuit line CL24 and a height h4 of the 26^{th} circuit line CL26, the height h2 of the 24^{th} circuit line CL24 may be higher than a height h1 of the 23^{rd} circuit line CL23, and the height h4 of the 26^{th} circuit line CL26 may be higher than a height h5 of the 27^{th} circuit line CL27.

Here, the heights h1, h2, h3, h4, and h5 of the circuit lines CL23 to CL27 may refer to the heights of the upper surfaces of the circuit lines CL23 to CL27 from the substrate 101.

Accordingly, the upper surface of the second protective layer 112 may be formed to correspond to the heights h1, h2, h3, h4, and h5 of the circuit lines CL23 to CL27. That is, the second protective layer 112 may have a convex shape that protrudes toward the encapsulation part 170 in the area in which the second protective layer 112 overlaps the second anode electrode ANO2 in the thickness direction (the third direction DR3). That is, the second protective layer 112 may have a convex shape that protrudes toward the encapsulation part 170 in the area in which the second protective layer 112 overlaps the second circuit line CL2 (see FIG. 3) and the second light-emitting area EA2 in the thickness direction (the third direction DR3).

Since the second anode electrode ANO2 disposed on the second protective layer 112 may be disposed to correspond to the curve of the upper surface of the second protective layer 112, the second anode electrode ANO2 may have a convex shape.

Accordingly, the shape of the second anode electrode ANO2 can be formed to a desired shape more smoothly. In addition, it is also possible to increase the degree of freedom related to the design of the layout of the display panel 100.

Since the second anode electrode ANO2 has a convex shape in the direction in which light is emitted, it is possible to improve the color viewing angle characteristics and enable the low-power driving of the display apparatus, thereby reducing power consumption.

As described above, the second sub-pixel SP2 has been described as an example, but the description thereof may be applied to the first sub-pixel SP1 and the third sub-pixel SP3 in the same manner.

A display apparatus according to various embodiments of the present specification may be described as follows.

A display apparatus according to embodiments of the present disclosure includes a substrate on which a first sub-pixel, a second sub-pixel, and a third sub-pixel are disposed, a first circuit line disposed on the substrate, a thin film transistor disposed between the substrate and the first circuit line, a first protective layer disposed on the first circuit line and the thin film transistor, a second circuit line disposed on the first protective layer, a second protective layer disposed on the second circuit line, and a first anode electrode of the first sub-pixel disposed on the second protective layer, in which the first protective layer has a different thickness in an area in which the first protective layer overlaps the first anode electrode.

According to various embodiments of the present specification, in an area in which the first protective layer overlaps the first anode electrode, the first protective layer may include a trench recessed in a thickness direction, and the second circuit line may be disposed in the trench.

According to various embodiments of the present specification, a height of an upper surface of the second circuit line may be the same as a height of an upper surface of the first protective layer.

According to various embodiments of the present specification, the first circuit line may include at least one of a scan line that transmits a scan signal, an initialization line that transmits an initialization voltage, and a light-emitting control line that transmits a light-emitting control signal, in which the second circuit line may include at least one of a data line that transmits a data voltage, a high-potential power line that transmits a high-potential power voltage, an anode reset line that transmits an anode reset voltage, and a low-potential power line that transmits a low-potential power voltage.

According to various embodiments of the present specification, the second circuit line and the trench are provided as a plurality of second circuit lines and a plurality of trenches, respectively, and all the heights of the upper surfaces of the plurality of second circuit lines may be the same in the area in which the second circuit line overlaps the first anode electrode.

According to various embodiments of the present specification, the first circuit line may extend in a first direction, and the second circuit line may extend in a second direction intersecting the first direction.

According to various embodiments of the present specification, the second circuit line and the trench may be provided as a plurality of second circuit lines and a plurality of trenches, respectively, and in the area in which the second circuit line overlaps the first anode electrode, the heights of the upper surfaces of the plurality of second circuit lines may decrease from a periphery of a central portion of the first anode electrode toward one side and the other side in the first direction.

According to various embodiments of the present specification, the first anode electrode may be formed in a convex shape in a thickness direction.

According to various embodiments of the present specification, in the area in which the first protective layer overlaps the first anode electrode, a thickness of the first protective layer in a second overlapping area in which the first protective layer overlaps the second circuit line may be smaller than a thickness of the first protective layer in a second non-overlapping area in which the first protective layer does not overlap the second circuit line.

According to various embodiments of the present specification, in the area in which the first protective layer overlaps the first anode electrode, a thickness of the first protective layer in a first overlapping area in which the first protective layer overlaps the first circuit line may be smaller than a thickness of the first protective layer in a first non-overlapping area in which the first protective layer does not overlap the first circuit line.

According to various embodiments of the present specification, the display apparatus may further include a second anode electrode of a second sub-pixel, which is disposed on a second protective layer, in which, in an area in which the first protective layer overlaps the second anode electrode, the thickness of the first protective layer in a second overlapping area in which the first protective layer overlaps the second circuit line may be smaller than the thickness of the first protective layer in a second non-overlapping area in which the first protective layer does not overlap the second circuit line.

According to various embodiments of the present specification, in the area in which the first protective layer overlaps the first anode electrode, an upper surface of the first protective layer may be flat, and in the area in which the first protective layer overlaps the second anode electrode, the first protective layer may include a trench recessed from the upper surface thereof.

According to various embodiments of the present specification, the first sub-pixel may emit red light, and the second sub-pixel may emit blue light.

According to various embodiments of the present specification, in the area in which the second protective layer overlaps the first anode electrode, the second protective layer may have a convex shape toward the first anode electrode, and the first anode electrode may have a convex shape corresponding to the convex shape of the second protective layer.

According to embodiments of the present specification, there is provided a display apparatus including a substrate on which a first sub-pixel, a second sub-pixel, and a third sub-pixel are disposed, a first circuit line disposed on the substrate, a thin film transistor disposed between the substrate and the first circuit line, a first protective layer disposed on the first circuit line and the thin film transistor, a second circuit line disposed on the first protective layer, a second protective layer disposed on the second circuit line, and a first anode electrode of the first sub-pixel disposed on the second protective layer, in which, in an area in which the first protective layer overlaps the first anode electrode, the first protective layer includes a trench recessed in a thickness direction, and the second circuit lines is disposed in the trench.

According to various embodiments of the present specification, in the area in which the first protective layer overlaps the first anode electrode, a thickness of the first protective layer in a second overlapping area in which the first protective layer overlaps the second circuit line may be smaller than a thickness of the first protective layer in a second non-overlapping area in which the first protective layer does not overlap the second circuit line.

According to various embodiments of the present specification, a height of an upper surface of the second circuit line may be the same as a height of an upper surface of the first protective layer.

According to various embodiments of the present specification, the second circuit line and the trench may be provided as a plurality of second circuit lines and a plurality of trenches, respectively, and all the heights of the upper surfaces of the plurality of second circuit lines may be the same in the area in which the second circuit line overlaps the first anode electrode.

According to various embodiments of the present specification, the first circuit line may extend in a first direction, and the second circuit line may extend in a second direction intersecting the first direction.

According to various embodiments of the present specification, the second circuit line and the trench may be provided as a plurality of second circuit lines and a plurality of trenches, respectively, and in the area in which the second circuit line overlaps the first anode electrode, the heights of the upper surfaces of the plurality of second circuit lines may decrease from a periphery of a central portion of the first anode electrode toward one side and the other side in the first direction.

Although the embodiments have been described above with reference to the accompanying drawings, those skilled in the art to which the present specification pertains will be able to understand that the above-described technical configuration can be carried out in other specific forms without changing the technical spirit or essential features thereof. Accordingly, it should be understood that the above-described embodiments are illustrative and not restrictive in all respects. In addition, the scope of the embodiments is determined by the appended claims rather than detailed description. In addition, the meaning and scope of the claims and all changed or modified forms derived from the equivalent concept thereof should be construed as being included in the scope of the embodiments.

What is claimed is:

1. A display apparatus, comprising:
a substrate on which a first sub-pixel, a second sub-pixel, and a third sub-pixel are disposed;
a first circuit line disposed on the substrate;
a thin film transistor disposed between the substrate and the first circuit line;
a first protective layer disposed on the first circuit line and the thin film transistor;
a second circuit line disposed on the first protective layer;
a second protective layer disposed on the second circuit line; and
a first anode electrode of the first sub-pixel, which is disposed on the second protective layer,
wherein the first protective layer has a different thickness in an area in which the first protective layer overlaps the first anode electrode.

2. The display apparatus of claim 1, wherein, in the area in which the first protective layer overlaps the first anode electrode, the first protective layer includes a trench recessed in a thickness direction, and the second circuit line is disposed in the trench.

3. The display apparatus of claim 2, wherein a height of an upper surface of the second circuit line is same as a height of an upper surface of the first protective layer.

4. The display apparatus of claim 3, wherein the first circuit line includes at least one of a scan line that transmits a scan signal, an initialization line that transmits an initialization voltage, and a light-emitting line that transmits a light-emitting control signal, and
the second circuit line includes at least one of a data line that transmits a data voltage, a high-potential power line that transmits a high-potential power voltage, an anode reset line that transmits an anode reset voltage, and a low-potential power voltage line that transmits a low-potential power voltage.

5. The display apparatus of claim 2, wherein the second circuit line and the trench are provided as a plurality of second circuit lines and a plurality of trenches, respectively, and
in an area in which the second circuit line overlaps the first anode electrode, all heights of upper surfaces of the plurality of second circuit lines are same.

6. The display apparatus of claim 2, wherein the first circuit line extends in a first direction, and the second circuit line extends in a second direction intersecting the first direction.

7. The display apparatus of claim 6, wherein the second circuit line and the trench are provided as a plurality of second circuit lines and a plurality of trenches, respectively, and
in an area in which the second circuit line overlaps the first anode electrode, heights of upper surfaces of the plurality of second circuit lines decrease from a periphery of a central portion of the first anode electrode toward one side and the other side in the first direction.

8. The display apparatus of claim 7, wherein the first anode electrode is formed in a convex shape in the thickness direction.

9. The display apparatus of claim 1, wherein, in the area in which the first protective layer overlaps the first anode electrode, a thickness of the first protective layer in a second overlapping area in which the first protective layer overlaps the second circuit line is smaller than a thickness of the first protective layer in a second non-overlapping area in which the first protective layer does not overlap the second circuit line.

10. The display apparatus of claim 1, wherein, in the area in which the first protective layer overlaps the first anode electrode, a thickness of the first protective layer in a first overlapping area in which the first protective layer overlaps the first circuit line is smaller than a thickness of the first protective layer in a first non-overlapping area in which the first protective layer does not overlap the first circuit line.

11. The display apparatus of claim 10, further comprising a second anode electrode of the second sub-pixel, which is disposed on the second protective layer,
wherein, in an area in which the first protective layer overlaps the second anode electrode, a thickness of the first protective layer in a second overlapping area in which the first protective layer overlaps the second circuit line is smaller than a thickness of the first protective layer in a second non-overlapping area in which the first protective layer does not overlap the second circuit line.

12. The display apparatus of claim 11, wherein an upper surface of the first protective layer is flat in the area in which the first protective layer overlaps the first anode electrode, and
in the area in which the first protective layer overlaps the second anode electrode, the first protective layer includes a trench recessed from an upper surface thereof.

13. The display apparatus of claim 12, wherein the first sub-pixel is configured to emit red light, and the second sub-pixel is configured to emit blue light.

14. The display apparatus of claim 10, wherein, in an area in which the second protective layer overlaps the first anode electrode, the second protective layer has a convex shape toward the first anode electrode, and
the first anode electrode has a convex shape corresponding to the convex shape of the second protective layer.

15. The display apparatus of claim 1, wherein an upper surface of the second circuit line protrudes from the upper surface of the first protective layer toward the second protective layer.

16. The display apparatus of claim 12, wherein the second circuit line and the trench are provided as a plurality of second circuit lines and a plurality of trenches, respectively, and
at least parts of the plurality of second circuit lines overlap the second anode electrode in a thickness direction, and the at least parts of the plurality of second circuit lines which overlap the second anode electrode in the thickness direction are disposed in the plurality of trenches.

17. The display apparatus of claim 16, wherein all heights of upper surfaces of the plurality of second circuit lines disposed in the plurality of trenches are same.

18. The display apparatus of claim 16, wherein in an area in which the plurality of second circuit lines overlap the second anode electrode in the thickness direction, heights of upper surfaces of the plurality of second circuit lines are different.

19. The display apparatus of claim 18, wherein in the area in which the plurality of second circuit lines overlap the second anode electrode, heights of the upper surfaces of the plurality of second circuit lines decrease from a periphery of a central portion of the second anode electrode toward one side and the other side in a first direction where the first circuit line extends.

20. The display apparatus of claim 16, wherein in an area in which the plurality of trenches overlap the second anode electrode in the thickness direction, recessed depths of at least some of the plurality of trenches are different.

21. A display apparatus, comprising:
a substrate on which a first sub-pixel, a second sub-pixel, and a third sub-pixel are disposed;
a first circuit line disposed on the substrate;
a thin film transistor disposed between the substrate and the first circuit line;
a first protective layer disposed on the first circuit line and the thin film transistor;
a second circuit line disposed on the first protective layer;
a second protective layer disposed on the second circuit line; and
a first anode electrode of the first sub-pixel, which is disposed on the second protective layer,
wherein, in an area in which the first protective layer overlaps the first anode electrode, the first protective layer includes a trench recessed in a thickness direction, and the second circuit line is disposed in the trench.

22. The display apparatus of claim 21, wherein, in the area in which the first protective layer overlaps the first anode electrode, a thickness of the first protective layer in a second overlapping area in which the first protective layer overlaps the second circuit line is smaller than a thickness of the first protective layer in a second non-overlapping area in which the first protective layer does not overlap the second circuit line.

23. The display apparatus of claim 21, wherein a height of an upper surface of the second circuit line is same as a height of an upper surface of the first protective layer.

24. The display apparatus of claim 21, wherein the second circuit line and the trench are provided as a plurality of second circuit lines and a plurality of trenches, respectively, and
in an area in which the second circuit line overlaps the first anode electrode, all heights of upper surfaces of the plurality of second circuit lines are same.

25. The display apparatus of claim 21, wherein the first circuit line extends in a first direction, and the second circuit line extends in a second direction intersecting the first direction.

26. The display apparatus of claim 25, wherein the second circuit line and the trench are provided as a plurality of second circuit lines and a plurality of trenches, respectively, and
in an area in which the second circuit line overlaps the first anode electrode, heights of upper surfaces of the plurality of second circuit lines decrease from a periphery of a central portion of the first anode electrode toward one side and the other side in the first direction.

27. The display apparatus of claim 21, wherein the second circuit line and the trench are provided as a plurality of second circuit lines and a plurality of trenches, respectively, and
at least parts of the plurality of second circuit lines overlap the first anode electrode in the thickness direction, and the at least parts of the plurality of second circuit lines which overlap the first anode electrode in the thickness direction are disposed in the plurality of trenches.

28. The display apparatus of claim 27, wherein in an area in which the plurality of trenches overlap the first anode electrode in the thickness direction, recessed depths of at least some of the plurality of trenches are different.
